(19) United States
(12) Patent Application Publication
(10) Pub. No.: US 2025/0081616 A1
(43) Pub. Date: Mar. 6, 2025

(54) METHOD FOR PREPARING SEMICONDUCTOR DEVICE, ARRAY SUBSTRATE AND DISPLAY PANEL

(71) Applicant: HKC CORPORATION LIMITED, Shenzhen (CN)

(72) Inventors: Guangsheng LI, Shenzhen (CN); Lei Jiang, Shenzhen (CN); Xueyong Huang, Shenzhen (CN); Ning Ye, Shenzhen (CN); Hejun Ning, Shenzhen (CN); Chengshun Zhu, Shenzhen (CN); Junfeng Xie, Shenzhen (CN)

(73) Assignee: HKC CORPORATION LIMITED, Shenzhen (CN)

(21) Appl. No.: 18/815,866

(22) Filed: Aug. 27, 2024

(30) Foreign Application Priority Data
Aug. 30, 2023 (CN) 202311105008.X

(51) Int. Cl. H01L 27/12; H01L 25/16; H01L 29/66; H01L 29/786

(52) U.S. Cl. CPC H10D 86/60; H01L 25/167; H10D 30/031; H10D 30/6755; H10D 86/0221; H10D 86/423

(57) ABSTRACT

A method for preparing a semiconductor device includes: forming a metal oxide semiconductor layer on a substrate; forming a second insulating dielectric layer on a side of the metal oxide semiconductor layer away from the substrate; wherein further including: forming a metal oxide isolation layer on a side of the second insulating dielectric layer away from the substrate; wherein the metal oxide isolation layer is in contact with a surface of the second insulating dielectric layer away from the substrate, a concentration of elemental oxygen in the metal oxide isolation layer is greater than a concentration of elemental oxygen in the second insulating dielectric layer, and the concentration of elemental oxygen in the second insulating dielectric layer is greater than a concentration of elemental oxygen in the metal oxide semiconductor layer. An array substrate and a display panel are also provided.

### CROSS-REFERENCE TO RELATED APPLICATIONS

This application claims priority to Chinese Patent Application No. 202311105008X, filed on Aug. 30, 2023, the content of which is herein incorporated by reference in its entirety.

### TECHNICAL FIELD

The present disclosure relates to the technical field of displays, and in particular to a method for preparing a semiconductor device, an array substrate and a display panel.

### BACKGROUND

At present, active matrix substrates used in organic electroluminescent (OLED) display devices, Mini LED (light emitting diode) display devices and the like usually use thin film transistors with silicon as a semiconductor layer. The thin film transistors may include low-temperature polycrystalline silicon semiconductor thin film transistors (hereinafter referred to as “LTPS TFT”) and low-temperature polycrystalline silicon oxide semiconductor thin film transistors (hereinafter referred to as “LTPO TFT”). However, in recent years, the demand for high definition, high refresh rate, and large-scale display products has gradually increased.

At present, the use of high-migration metal oxide semiconductor devices is being promoted to replace LTPS TFT and LTPO TFT, high-migration metal oxide semiconductor devices can achieve high mobility in performance, and have a more simplified device structure and low-temperature process. The investment required to manufacture each square meter of the product and the costs are lower, and the product yield is higher. Therefore, the high-migration metal oxide semiconductor devices can meet the demand for mass production of OLED above G8.5 and above, and have strong comprehensive competitiveness.

Metal oxide semiconductor devices can be used in high-end display devices such as OLED and Mini-LED. However, metal oxide TFT devices are prone to problems such as poor characteristics and electron mobility degradation during operation.

### SUMMARY

The present disclosure provides a method for preparing a semiconductor device, an array substrate and a display panel.

A technical solution adopted in the present disclosure is to provide a method for preparing a semiconductor device, which includes: forming a metal oxide semiconductor layer on a substrate; forming a second insulating dielectric layer on a side of the metal oxide semiconductor layer away from the substrate; forming a metal oxide isolation layer on a side of the second insulating dielectric layer away from the substrate; wherein the metal oxide isolation layer is in contact with a surface of the second insulating dielectric layer away from the substrate, a concentration of elemental oxygen in the metal oxide isolation layer is greater than a concentration of elemental oxygen in the second insulating dielectric layer, and the concentration of elemental oxygen in the second insulating dielectric layer is greater than a concentration of elemental oxygen in the metal oxide semiconductor layer.

Another technical solution adopted in the present disclosure is to provide an array substrate, which includes a semiconductor device, wherein the semiconductor device is prepared by a method, comprising: forming a metal oxide semiconductor layer on a substrate; forming a second insulating dielectric layer on a side of the metal oxide semiconductor layer away from the substrate; and forming a metal oxide isolation layer on a side of the second insulating dielectric layer away from the substrate; wherein the metal oxide isolation layer is in contact with a surface of the second insulating dielectric layer away from the substrate, a concentration of elemental oxygen in the metal oxide isolation layer is greater than a concentration of elemental oxygen in the second insulating dielectric layer, and the concentration of elemental oxygen in the second insulating dielectric layer is greater than a concentration of elemental oxygen in the metal oxide semiconductor layer.

Another technical solution adopted in the present disclosure is to provide a display panel, which includes: an array substrate; and a light emitting layer, disposed on a side of the array substrate and electrically connected to the array substrate; wherein the array substrate comprises a semiconductor device prepared by a method comprising: forming a metal oxide semiconductor layer on a substrate; forming a second insulating dielectric layer on a side of the metal oxide semiconductor layer away from the substrate; and forming a metal oxide isolation layer on a side of the second insulating dielectric layer away from the substrate; wherein the metal oxide isolation layer is in contact with a surface of the second insulating dielectric layer away from the substrate, a concentration of elemental oxygen in the metal oxide isolation layer is greater than a concentration of elemental oxygen in the second insulating dielectric layer, and the concentration of elemental oxygen in the second insulating dielectric layer is greater than a concentration of elemental oxygen in the metal oxide semiconductor layer.

### BRIEF DESCRIPTION OF THE DRAWINGS

In order to more clearly illustrate the technical solutions of the embodiments of the present disclosure, the drawings for the description of the embodiment will be described in brief. Obviously, the drawings in the following description are only some of the embodiments of the present disclosure. For a person of ordinary skill in the art, other drawings may be obtained based on the following drawings without any creative work.

FIG. 1 is a flow chart of a method for preparing a semiconductor device according to the first embodiment of the present disclosure.

FIG. 2 is a schematic specific structure view of operation S00.

FIG. 3 is a schematic structure view of operation S01.

FIG. 4 is a schematic specific structure view of operation S02.

FIG. 5 is a schematic specific structure view of operation S03.

FIG. 6 is a schematic specific structure view of patterning a metal oxide isolation layer;

FIG. 7 is a schematic specific structure view of operation S05.

FIG. 8 is a schematic specific structure view of operation S051 and operation S052.

FIG. 9 is a schematic structure view of operation S06.

FIG. 10 is a schematic structure view of operation S07.

FIG. 11 is a schematic structure view of operation S08.

FIG. 12 is a flow chart of a method for preparing a semiconductor device according to the second embodiment of the present disclosure.

FIG. 13 is a schematic specific structure view of removing the metal oxide isolation layer.

FIG. 14 is a schematic structure view of operation S051 in the second embodiment.

FIG. 15 is a schematic structure view of operation S052 in the second embodiment.

FIG. 16 is a schematic structure view of operation S06 in the second embodiment.

FIG. 17 is a schematic structure view of operation S07 in the second embodiment.

FIG. 18 is a schematic structure view of operation S08 in the second embodiment.

FIG. 19 is a schematic view of the variation of gate voltage and drain current of a semiconductor device prepared without supply of oxygen.

FIG. 20 is a schematic view of the variation of gate voltage and drain current of a semiconductor device prepared with supply of oxygen.

FIG. 21 is a schematic view of comparing the stability test results of the semiconductor device prepared using the method of the second embodiment and the semiconductor device of the comparative example.

FIG. 22 is a flow chart of a method for preparing an array substrate according to an embodiment of the present disclosure.

FIG. 23 is a schematic structure view of operation S09.

FIG. 24 is a schematic structure view of operation S010.

FIG. 25 is a structure schematic view of a display panel according to an embodiment of the present disclosure.

Description of reference numerals: 10—semiconductor device; 101—substrate; 102—metal oxide semiconductor layer; 103—second insulating dielectric layer; 104—metal oxide isolation layer; 105—bottom gate electrode; 106—first insulating dielectric layer; 107—top gate electrode; 108—first patterned hole; 109—first insulating protective layer; 110—second patterned hole; 111—source-drain electrode; 112—second insulating protective layer; 113—third patterned hole; 114—anode electrode; 100—array substrate; 200—light emitting layer; 1000—display panel.

### DETAILED DESCRIPTIONS

Technical solutions of the embodiments of the present disclosure will be clearly and comprehensively described by referring to the accompanying drawings. Obviously, the embodiments described herein are only a part of, but not all of, the embodiments of the present disclosure. Based on the embodiments in the present disclosure, all other embodiments obtained by a person of ordinary skill in the art without any creative work shall fall within the scope of the present disclosure.

In the following description, for the purpose of explanation rather than limitation, specific details such as specific system structural, interfaces and technologies are set forth, in order to provide a fully understanding of the present disclosure.

Terms “first”, “second”, and “third” in the embodiments of the present disclosure are only used for descriptive purposes, and cannot be understood as indicating or implying relative importance or implicitly indicating the number of indicated technical features. Therefore, features defined with “first”, “second”, and “third” may explicitly or implicitly include at least one of the features. In the description of the present disclosure, “a plurality of” means at least two, such as two, three, etc., unless specifically defined otherwise. In the embodiments of the present disclosure, all directional indications (such as up, down, left, right, front, back, etc.) are only used to explain the relative position relationship, motion, etc. between components in a specific attitude (as shown in the figure). If the specific attitude changes, the directional indication will change accordingly. In addition, terms “including”, “having”, and any variations thereof are intended to cover non-exclusive inclusions. For example, a process, method, system, product, or device that includes a series of operations or units is not limited to the listed operations or units, but optionally includes unlisted operations or units, or optionally also includes other operations or units inherent to these processes, methods, products or equipment.

The reference to “an embodiment” means that a specific feature, structure or characteristic described in connection with an embodiment may be included in at least one embodiment of the present disclosure. The appearance of “an embodiment” in various places in the specification does not necessarily refer to the same embodiment, nor is it an independent or alternative embodiment mutually exclusive with other embodiments. It is understood explicitly and implicitly by those skilled in the art that the embodiments described in the present disclosure can be combined with other embodiments.

In metal oxide TFTs, insulating dielectric layer covering a metal oxide semiconductor layer may generate a higher defect energy level density, which results in the capture of the oxide semiconductor layer's work carriers by the defect energy levels, reducing the carrier concentration and causing problems such as poor semiconductor device characteristics and electron mobility degradation. Especially in a drive circuit of high refresh rates and high-resolution products, the current demand for semiconductor devices is higher, and more stable semiconductor devices are required to safeguard the product characteristics.

Therefore, the present disclosure provides a method for preparing a metal oxide semiconductor device that can reduce the defect energy level density of an insulating dielectric layer covering a metal oxide semiconductor layer. The metal oxide semiconductor device prepared in the present disclosure can be applied to an array substrate of a display panel such as an OLED or a Mini LED.

The present disclosure is described in detail below in connection with the accompanying drawings and embodiments.

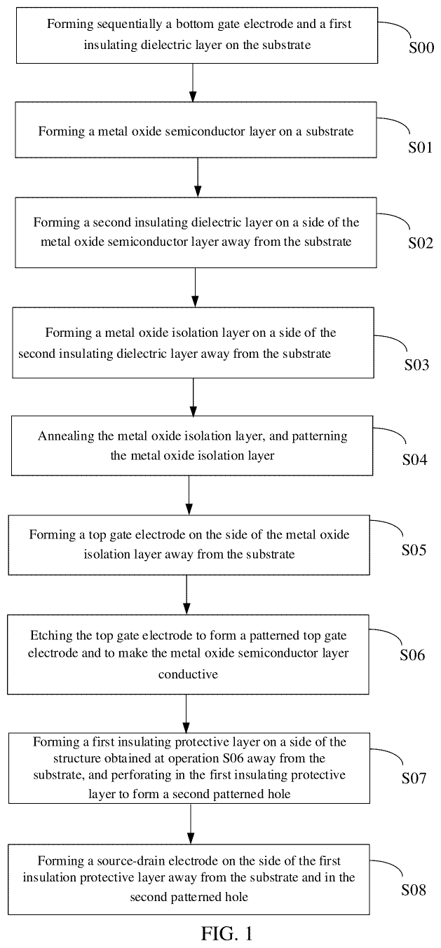

Referring to FIG. 1, FIG. 1 is a flow chart of a method for preparing a semiconductor device according to the first embodiment of the present disclosure. The present disclosure provides a method for preparing a semiconductor device 10, including the following operations.

Operation S01: Forming a metal oxide semiconductor layer on a substrate.

Forming the metal oxide semiconductor layer 102 on the substrate 101 can be understood as being formed by sputtering directly on the substrate 101, or being formed by further sputtering of the metal oxide semiconductor layer 102 after the bottom gate electrode 105 and the first insulating dielectric layer 106 are formed on the substrate 101. This present disclosure mainly takes as an example that after the bottom gate electrode 105 and the first insulating dielectric layer 106 are formed on the substrate 101, further sputtering to form a metal oxide semiconductor layer 102. In some embodiments, before forming a metal oxide semiconductor layer 102 on the substrate 101, further includes:

Operation S00: Forming sequentially a bottom gate electrode and a first insulating dielectric layer on the substrate.

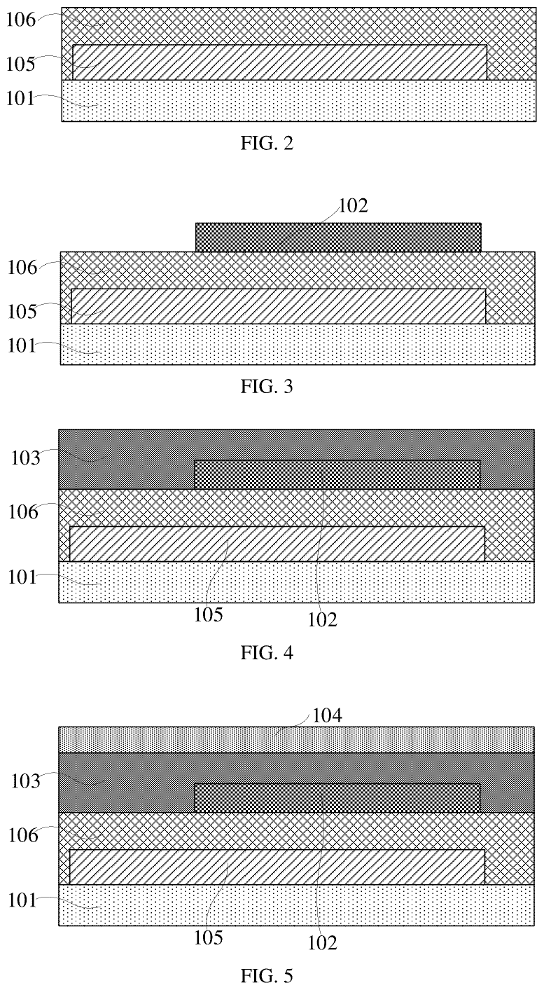

Referring to FIG. 2, FIG. 2 is a schematic specific structure view of operation S00. A bottom gate electrode 105 and a first insulating dielectric layer 106 are sequentially formed on the substrate 101. the bottom gate electrode 105 is deposited on the substrate 101 by magnetron sputtering, and the bottom gate electrode 105 may be set as a monolayer, a bilayer, a multilayer metal alloy or pure metal (the metal alloy or the pure metal including, but not limited to, Cu, Mo, Al, Ti, Nb, Mg), and pattern the bottom gate electrode 105 by coating, exposing, developing and wet etching stripping.

After the bottom gate electrode 105 is patterned, a first insulating dielectric layer 106 is formed on the surface of the bottom gate electrode 105 by chemical vapor deposition, and the first insulating dielectric layer 106 covers the bottom gate electrode 105. The first insulating dielectric layer 106 includes but is not limited to a combination of film layers of silicon oxide, silicon nitride, and silicon nitride oxide, wherein the first insulating dielectric layer 106 is a composite film layer consisting of at least two of the above mentioned layers, and a film layer of the first insulating dielectric layer 106 near the bottom gate electrode 105 is one of the silicon nitride film layers and silicon nitride oxide film layers, and a film layer near the top is a silicon oxide film layer.

Referring to FIG. 3, FIG. 3 is a schematic structure view of operation S01. As shown in FIG. 3, a metal oxide semiconductor layer 102 is formed on the substrate 101 by magnetron sputtering. Wherein, the substrate 101 may be made of a transparent material such as glass. The metal elements of the metal oxide semiconductor layer 102 include one or more of In, Ga, Zn, and Sn. For example, the metal oxide semiconductor layer 102 may be one or more of zinc oxide, tin oxide, indium oxide, gallium oxide, indium zinc oxide, zinc tin oxide, indium tin oxide, indium gallium zinc oxide, indium tin zinc oxide, and the like. In a specific embodiment, the metal element material of the metal oxide semiconductor layer 102 includes but is not limited to, In, Ga, Zn, and Sn to achieve the characteristics of medium mobility of 5%-10%; then completing the annealing treatment with annealing treatment temperature range of 260° C.-340° C. and annealing time range of 45 min-75 min. The patterned metal oxide semiconductor layer 102 is further formed by coating, exposing, developing, etching, and stripping.

It could be understood that since the bottom gate electrode 105 and the first insulating dielectric layer 106 are sequentially formed on the substrate 101, in operation S01, the metal oxide semiconductor layer 102 is formed on the first insulating dielectric layer 106 by magnetron sputtering. It could be understood that the semiconductor device 10 provided in the present disclosure can include only the top gate electrode 107 (see FIG. 8), include only the bottom gate electrode 105, or include only a dual gate with the top gate electrode 107 and the bottom gate electrode 105, and the present disclosure is not limit this, in this regard, the semiconductor device 10 with a dual gate is mainly described as an example in the embodiments of the present disclosure.

Operation S02: Forming a second insulating dielectric layer on a side of the metal oxide semiconductor layer away from the substrate.

Referring to FIG. 4, FIG. 4 is a schematic specific structure view of operation S02. As shown in FIG. 4, a second insulating dielectric layer 103 is formed on the side of the patterned metal oxide semiconductor layer 102 away from the substrate 101 by chemical vapor deposition, and the second insulating dielectric layer 103 covers the metal oxide semiconductor layer 102, wherein the material of the second insulating dielectric layer 103 includes but is not limited to silicon oxide, alumina oxide, etc. The thickness of the second insulating dielectric layer 103 is 100 nm-200 nm. In a specific embodiment, the material of the second insulating dielectric layer 103 is silicon oxide or aluminum oxide.

Operation S03: Forming a metal oxide isolation layer on a side of the second insulating dielectric layer away from the substrate.

Referring to FIG. 5, FIG. 5 is a schematic specific structure view of operation S03. A metal oxide isolation layer 104 is formed on a side of the second insulating dielectric layer 103 away from the substrate 101, and the metal oxide isolation layer 104 is in contact with a surface of the second insulating dielectric layer 103 away from the substrate 101.

In some embodiments, the operation includes forming the metal oxide isolation layer 104 by sputtering on the surface of the second insulating dielectric layer 103 away from the substrate 10 in an atmosphere containing oxygen; wherein the oxygen flow rate in the atmosphere containing oxygen accounts for more than or equal to 7% of the entire process gas, which is used to supply oxygen to the second insulating dielectric layer 103. The metal elements of the metal oxide isolation layer 104 include one or more of In, Ga, Zn, and Sn. For example, the metal oxide isolation layer 104 may be one or more of zinc oxide, tin oxide, indium oxide, gallium oxide, indium zinc oxide, zinc tin oxide, indium tin oxide, indium gallium zinc oxide, indium tin zinc oxide, and the like. Considering the principle of economy, it is preferred that the metal oxide isolation layer 104 is made of the same material as the metal oxide semiconductor layer 102, which is convenient for preparation and also saves the cost of preparation. In some embodiments, different materials may also be used for the preparation, to which the present disclosure does not limit.

In some embodiments, the concentration of elemental oxygen in the metal oxide isolation layer 104 is greater than the concentration of elemental oxygen in the second insulating dielectric layer 103, and the concentration of elemental oxygen in the second insulating dielectric layer 103 is greater than the concentration of elemental oxygen in the metal oxide semiconductor layer 102, to supply oxygen to the second insulating dielectric layer 103 through the metal oxide isolation layer 104, further enabling oxygen to diffuse through the second insulating dielectric layer 103 to the metal oxide semiconductor layer 102. After forming a metal oxide isolation layer 104 on the side of the second insulating dielectric layer 103 away from the substrate 101, it further includes:

Operation S04: Annealing the metal oxide isolation layer, and patterning the metal oxide isolation layer.

In some embodiments, the metal oxide isolation layer 104 is annealed under dry compressed air, making it easier for oxygen in the metal oxide isolation layer 104 to diffuse into the second insulating dielectric layer 103, and making it easier for oxygen in the second insulating dielectric layer 103 to diffuse into the metal oxide semiconductor layer 102. By forming the metal oxide isolation layer 104 on the side of the second insulating dielectric layer 103 away from the substrate 101, the metal oxide isolation layer 104 cannot only supply oxygen for the metal oxide semiconductor layer 102 but also prevent the oxygen in the metal oxide semiconductor layer 102 from running out and diffusing into the annealed chamber during the annealing treatment. The metal oxide isolation layer 104 covers the entire second insulating dielectric layer 103, which can better supply oxygen and prevent oxygen from running out of the metal oxide semiconductor layer 102. The thickness of the metal oxide isolation layer 104 is 20 nm-50 nm.

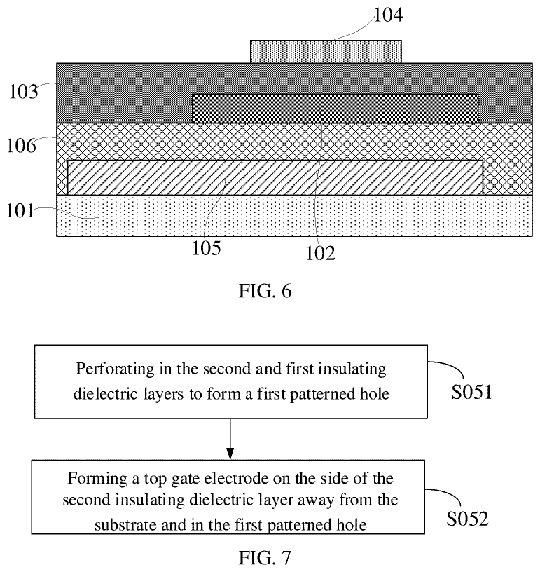

Referring to FIG. 6, FIG. 6 is a schematic specific structure view of patterning the metal oxide isolation layer. The metal oxide isolation layer 104 is patterned after annealing.

It could be understood that, as shown in FIG. 5, the metal oxide isolation layer 104 may be a continuous whole layer and cover the entire second insulating dielectric layer 103 for a better supply of oxygen of the second insulating dielectric layer 103. After annealing, the metal oxide isolation layer 104 can be completely removed to facilitate the subsequent operation of perforating in the second insulating dielectric layer 103, to simplify the process, or the metal oxide isolation layer 104 can be partially removed, i.e., the metal oxide isolation layer 104 can be patterned such that a portion of the metal oxide isolation layer 104 is retained between the second insulating dielectric layer 103 and the top gate electrode 107.

It could be understood that the portion of the metal oxide isolation layer 104 is retained between the second insulating dielectric layer 103 and the top gate electrode 107, which may increase the insulating effect between the top gate electrode 107 (refer to FIG. 8) and the metal oxide semiconductor layer 102; Moreover, removing the portion of the metal oxide isolation layer 104 can also allow a portion of the second insulating dielectric layer 103 to be exposed, which facilitates subsequent punching (refer to operation S05), the embodiments are next illustrated as an example of a metal oxide isolation layer 104 that is partially removed for patterning after annealing.

In an embodiment, the material of the metal oxide semiconductor layer 102 may be a metal oxide material having certain semiconductor characteristics. In some embodiments, the metal elements in the metal oxide semiconductor layer 102 include In, Ga, and Zn, wherein the In element content of the metal oxide semiconductor layer 102 is the same as that of other metal elements, in order to achieve the characteristics of a semiconductor device 10 with the medium mobility of 5%-10%. The metal oxide isolation layer 104 can be made of the same material as the metal oxide semiconductor layer 102, or a film structure composed of one or more materials with an In:Ga:Zn ratio range of 1˜8:1˜8:1˜8. For the metal oxide semiconductor layer 104 corresponding to the metal oxide semiconductor layer 102 with the same In element content and the identical monomer content of the other metal elements, the annealing time is in the range of 45 min-75 min, and the annealing temperature is in the range of 300° C.-450° C. The concentration and stability of semiconductor charge carriers are good in this temperature range.

In an embodiment, the material of the metal oxide semiconductor layer 102 may also use semiconductor materials with higher carrier concentrations. In some embodiments, the metal elements of the metal oxide semiconductor layer 102 include In Ga, Zn, and Sn; In addition, the material of the metal oxide semiconductor layer 102 also includes rare earth metal trace elements; Among them, the In element content of the metal oxide semiconductor layer 102 is higher than the monomer content of other metal elements, to achieve the characteristics of a semiconductor device with medium mobility of 20-50%. The metal oxide isolation layer 104 can be made of the same material as the metal oxide semiconductor layer 102, or a film structure composed of one or more materials with an In:Ga:Zn ratio range of 1˜8:1˜8:1˜8. For the metal oxide semiconductor layer 104 corresponding to the metal oxide semiconductor layer 102 which the content of In element is higher than the identical monomer content of the other metal elements, the annealing time is in the range of 45 min-75 min, and the annealing temperature is in the range of 260° C.-350° C. It is necessary to consider not only the supply of oxygen during the annealing treatment, but also the effect of hydrogen diffusion in the second insulating dielectric layer 103 on the metal oxide semiconductor layer 102. It is concluded through experiments that the temperature range is more effective in accomplishing the supply of oxygen without causing too much diffusion of hydrogen. For example, the annealing time can be 45 minutes, 50 minutes, 55 minutes, 60 minutes, 65 minutes, 70 minutes, and 75 minutes. The annealing temperatures can be 300° C., 320° C., 340° C., 360° C., 380° C., 400° C., 420° C., 440° C. After annealing the metal oxide isolation layer 104, it further includes:

Operation S05: Forming a top gate electrode on the side of the metal oxide isolation layer away from the substrate.

Among them, referring to FIG. 7, FIG. 7 is a schematic specific structure view of operation S05.

Operation S05 includes operation S051 and operation S052:

Operation S051: Perforating in the second and first insulating dielectric layers to form a first patterned hole.

Operation S052: Forming a top gate electrode on the side of the second insulating dielectric layer away from the substrate and in the first patterned hole.

Referring to FIG. 8, FIG. 8 is a schematic specific structure view of operation S051 and operation S052. The first patterned hole 108 is formed by coating, exposing, developing, and dry etching on a side of the second insulating dielectric layer 103 away from the substrate 101. The top gate electrode 107 is formed by magnetron sputtering, which can be set as a monolayer, a bilayer, a multilayer metal alloy or pure metal (the metal alloy or the pure metal including, but not limited to, Cu, Mo, Al, Ti, Nb, Mg), and is connected to the bottom gate electrode 105 through the first patterned hole 108.

Operation S06: Etching the top gate electrode to form a patterned top gate electrode and to make the metal oxide semiconductor layer conductive.

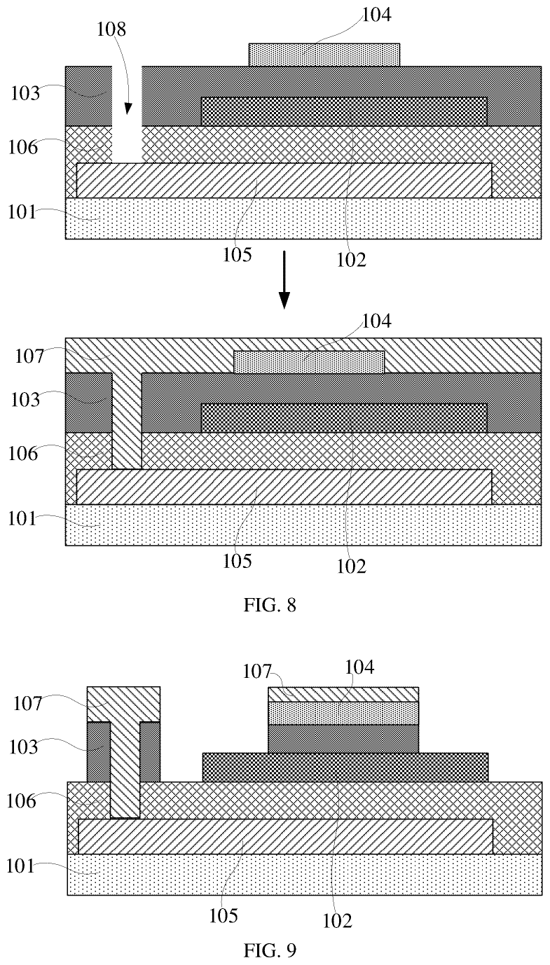

Referring to FIG. 9, FIG. 9 is a schematic structure view of operation S06. A patterned top gate electrode 107 is formed by coating, exposing, developing, and etching. Then, the second insulating dielectric layer 103 is etched by dry etching to expose the metal oxide semiconductor layer 102 not covered by the top gate electrode 107, and the exposed metal oxide semiconductor layer 102 is bombarded to make conductive by a gas plasma, which gas includes but is not limited to helium, argon.

Operation S07: Forming a first insulating protective layer on a side of the structure obtained at operation S06 away from the substrate, and perforating in the first insulating protective layer to form a second patterned hole.

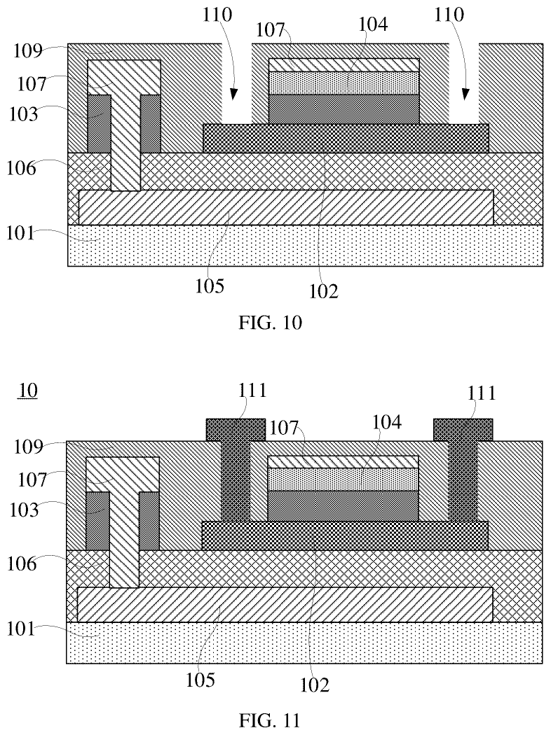

Referring to FIG. 10, FIG. 10 is a schematic structure view of operation S07. A first insulating protective layer 109 is formed by chemical vapor deposition, which includes but is not limited to, a monolayer of silicon oxide and a multilayer structure of silicon nitride, and the film layer near the top gate electrode 107 is a silicon oxide film layer. The first insulating protective layer 109 is also perforated by coating, exposing, developing, dry etching, and stripping to form a second patterned hole 110.

Operation S08: Forming a source-drain electrode on the side of the first insulation protective layer away from the substrate and in the second patterned hole.

Referring to FIG. 11. FIG. 11 is a schematic structure view of operation S08. the source-drain electrode 111 is formed by magnetron sputtering, the source-drain electrode 111 may be set as a monolayer, a bilayer, a multilayer metal alloy, or pure metal (the metal alloy or the pure metal including, but not limited to, Cu, Mo, Al, Ti, Nb, Mg), and pattern the source-drain electrode 111 by coating, exposing, developing and wet etching stripping, to complete the preparation of semiconductor device 10.

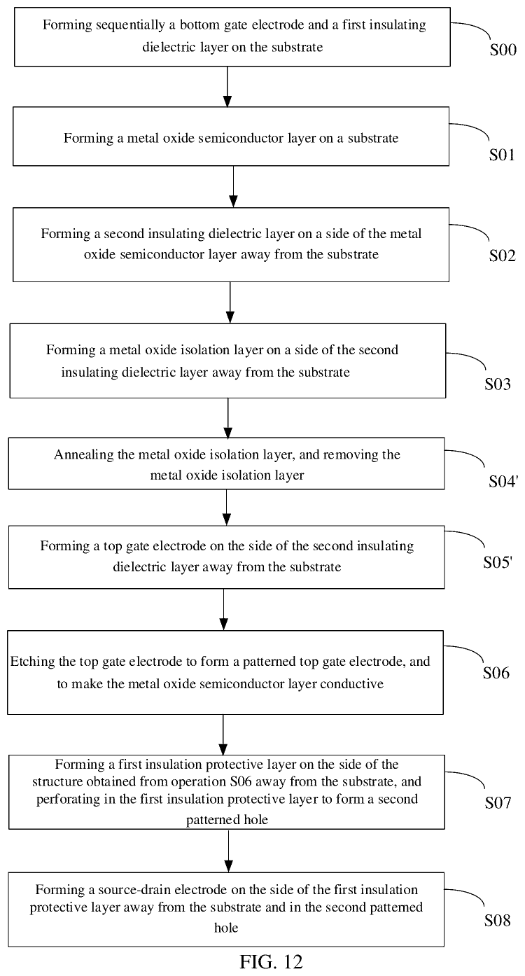

Referring to FIG. 12, FIG. 12 is a flow chart of a method for preparing a semiconductor device according to the second embodiment of the present disclosure. The method for preparing semiconductor device 10 provided in the second embodiment and the method for preparing provided in the first embodiment are basically the same, except that the method for preparing semiconductor device 10 provided in the second embodiment further includes operation S04 before (operation S05) forming a top gate electrode 107 on the side of the metal oxide isolation layer 104 away from the substrate 101, operation S04′:

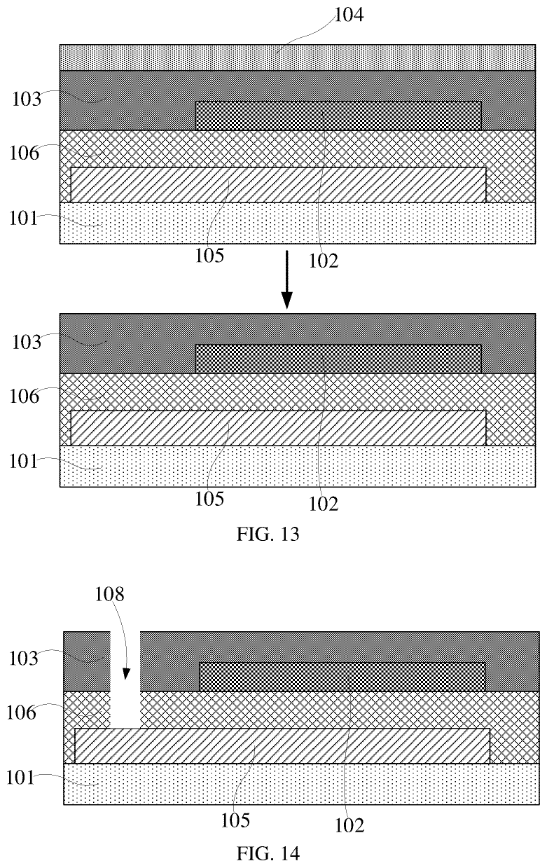

Annealing the metal oxide isolation layer, and removing the metal oxide isolation layer. Referring to FIG. 13. FIG. 13 is a schematic specific structure view of removing the metal

oxide isolation layer. As shown in FIG. 13, the metal oxide isolation layer 104 is removed by wet etching. If the metal oxide isolation layer 104 is set up as a whole layer during the preparation process, it will have an impact on the subsequent punching. Compared to the process of patterning the metal oxide isolation layer 104 which requires a mask, removing the metal oxide isolation layer 104 is more convenient, simplifies the process, and can further avoid TFT short circuits. Therefore, removing the metal oxide isolation layer 104 is illustrated in detail in the embodiment as an example.

Operations after removing the metal oxide isolation layer 104 will change as a result, so the subsequent operations will be explained again in the embodiment as follows:

Operation S05′: Forming a top gate electrode on the side of the second insulating dielectric layer away from the substrate.

Among them, operation S05′ includes S051 and S052:

Operation S051: Perforating in the second and first insulating dielectric layers to form a first patterned hole.

Referring to FIG. 14, FIG. 14 is a schematic structure view of operation S051 in the second embodiment. The first patterned hole 108 is formed by coating, exposing, developing, and dry etching.

Operation S052: Forming a top gate electrode on the side of the second insulating dielectric layer away from the substrate and in the first patterned hole.

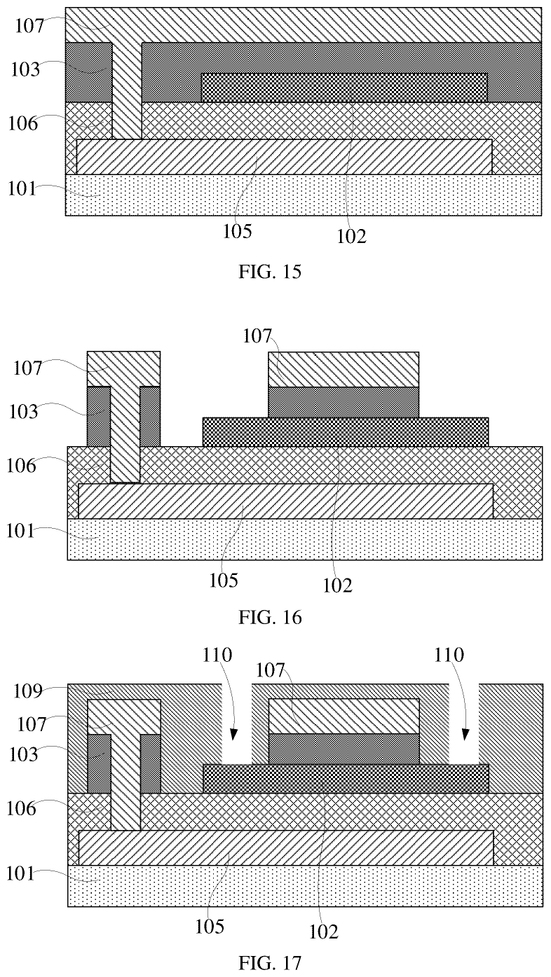

Referring to FIG. 15. FIG. 15 is a schematic structure view of operation S052 in the second embodiment. The top gate electrode 107 is formed by magnetron sputtering, the top gate electrode 107 may be set as a monolayer, a bilayer, a multilayer metal alloy, or pure metal (the metal alloy or the pure metal including, but not limited to, Cu, Mo, Al, Ti, Nb, Mg), and The top gate electrode 107 is connected to the bottom gate electrode 105 through the first patterned hole 108.

Operation S06: Etching the top gate electrode to form a patterned top gate electrode, and to make the metal oxide semiconductor layer conductive.

Referring to FIG. 16, FIG. 16 is a schematic structure view of operation S06 in the second embodiment. A patterned top gate electrode 107 is formed by coating, exposing, developing, and etching. Then, the second insulating dielectric layer 103 is etched by dry etching to expose the metal oxide semiconductor layer 102 not covered by the top gate electrode 107, and the exposed metal oxide semiconductor layer 102 is bombarded to make conductive by a gas plasma, which gas includes but is not limited to helium, argon.

Operation S07: Forming a first insulation protective layer on the side of the structure obtained from operation S06 away from the substrate, and perforating in the first insulation protective layer to form a second patterned hole.

Referring to FIG. 17, FIG. 17 is a schematic structure view of operation S07 in the second embodiment. A first insulating protective layer 109 is formed by chemical vapor deposition, which includes but is not limited to, monolayer/multilayer structure of silicon oxide or silicon nitride, and the film layer near the top gate electrode 107 is a silicon oxide film layer. The first insulating protective layer 109 is also perforated by coating, exposing, developing, dry etching, and stripping to form a second patterned hole 110.

Operation S08: Forming a source-drain electrode on the side of the first insulation protective layer away from the substrate and in the second patterned hole.

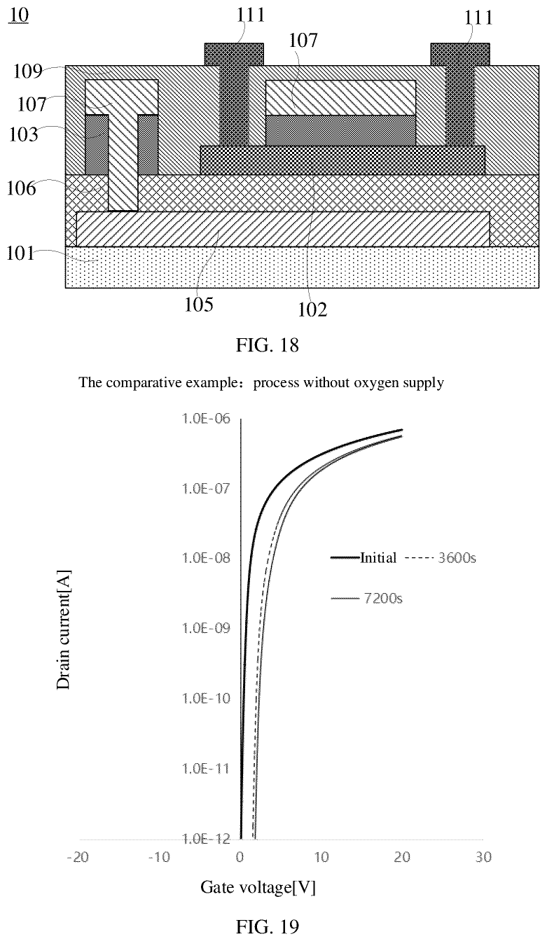

Referring to FIG. 18. FIG. 18 is a schematic structure view of operation S08 in the second embodiment, the source-drain electrode 111 is formed by magnetron sputtering, the source-drain electrode 111 may be set as a monolayer, a bilayer, a multilayer metal alloy, or pure metal (the metal alloy or the pure metal including, but not limited to, Cu, Mo, Al, Ti, Nb, Mg), and pattern the source-drain electrode 111 by coating, exposing, developing and wet etching stripping, to complete the preparation of semiconductor device 10.

The following are comparison results and test results of the semiconductor device prepared in the second embodiment of the present disclosure with the semiconductor device of the comparative example, the technical effects of the present disclosure will be further described below in conjunction with the accompanying drawings:

The semiconductor device prepared in the second embodiment: The specific method of supplying oxygen is to sputter a metal oxide isolation layer with a thickness of 0.02 mm in an oxygen atmosphere, and anneal the metal oxide isolation layer in dry air for 45 minutes at a temperature of 350° C. Among them, the metal oxide semiconductor layer adopts medium mobility material with a mobility of 5%.

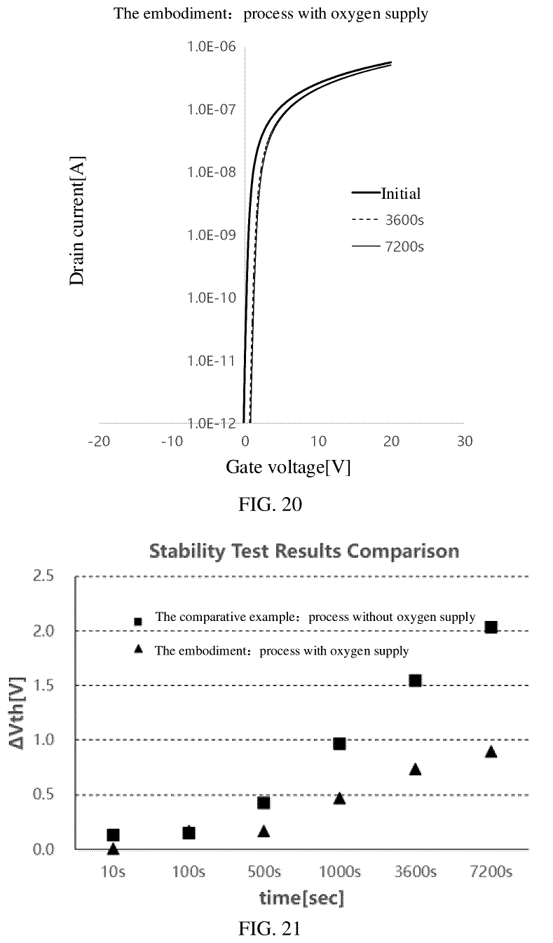

Referring to FIG. 19, FIG. 20, FIG. 21, Table 1, Table 2, FIG. 19 is a schematic view of the variation of gate voltage and drain current of a semiconductor device prepared without oxygen supply;

FIG. 20 is a schematic view of the variation of gate voltage and drain current of a semiconductor device prepared with oxygen supply; FIG. 21 is a schematic view of comparing the stability test results of the semiconductor device prepared using the method of the second embodiment and the semiconductor device of the comparative example. The specific conclusion is as follows:

The electrical properties of the semiconductor device of the comparative example were not significantly different from those of the semiconductor device of the second embodiment in terms of threshold voltage [Vth], electron mobility [μFE], and S-value (see Table 1), However, the stability of the semiconductor device of the second embodiment was significantly improved, and the electrical fluctuation (ΔVth) was reduced from 2.03V to 0.9V under the condition of applying bias voltage for a long period (2 hours) (see Table 2). The detailed stability measurement data are shown in FIG. 19, FIG. 20, and FIG. 21, and the stability of the semiconductor device prepared by the method for preparing the semiconductor device according to the second embodiment of the present disclosure was significantly improved compared to the comparative example.

TABLE 1
Comparison of electrical characteristic parameters
of semiconductor device between the second
embodiment and the comparative example

| | Vth | μ_{FE} | S-Value |
|---|---|---|---|
| Test sample | [V] | [cm²/Vs] | [V/dec] |
| the second | 0.73 | 9.4 | 0.34 |
| embodiment | | | |
| the comparative | 0.85 | 9.4 | 0.30 |
| example | | | |

TABLE 2
Comparison of electrical stability testing of semiconductor device
between the second embodiment and the comparative example

| | the second | the comparative |
|---|---|---|
| | embodiment | example |
| Test time | ΔVth[V] | ΔVth[V] |

| | | | |
|---|---|---|---|
| 10 | s | 0.01 | 0.13 |
| 100 | s | 0.17 | 0.15 |
| 500 | s | 0.17 | 0.42 |
| 1000 | s | 0.47 | 0.97 |
| 3600 | s | 0.74 | 1.54 |
| 7200 | s | 0.90 | 2.03 |

The semiconductor device 10 prepared in the disclosure can be applied in the preparation process of the semiconductor devices with medium mobility, which effectively improves the stability of semiconductor device 10 while ensuring that the basic indicators of semiconductor device 10 meet the standards. Its electrical fluctuation is reduced by 55.7% in long-term forward continuous bias testing, and it is directly applied to large-sized high-end OLED and glass-based Mini LED products, effectively reducing problems such as burning, brightness, and Mura taste caused by poor characteristics. The semiconductor device 10 prepared in the disclosure can also be applied in the preparation process of high mobility oxide semiconductor device 10, which effectively ensures the stability of semiconductor device 10 while ensuring its high electron mobility. This can improve the product design margin, shorten the W value, reduce the TFT/GDM area, and ensure stable mass production and normal use of products made using semiconductor device 10. Moreover, based on existing manufacturing equipment and materials, the preparation method of this disclosure can effectively improve the stability of semiconductor device 10 and minimize the manufacturing cost of products made using the semiconductor device 10 without undergoing equipment changes, mask additions, and design changes.

A method for preparing the semiconductor device 10 is provided according to the embodiment of the present disclosure, including forming a metal oxide semiconductor layer 102 on the substrate 101; forming the second insulating dielectric layer 103 on the side of the metal oxide semiconductor layer 102 away from the substrate 101; further comprising: forming the metal oxide isolation layer 104 on one side of the second insulating dielectric layer 103 away from the substrate 101; wherein, the metal oxide isolation layer 104 is in contact with the surface of the second insulating dielectric layer 103 away from the substrate 101, the concentration of oxygen element in the metal oxide isolation layer 104 is greater than that in the second insulating dielectric layer 103, and the concentration of oxygen element in the second insulating dielectric layer 103 is greater than that in the metal oxide semiconductor layer 102. This preparation method effectively improves the stability and electron mobility of semiconductor device 10 by forming a metal oxide isolation layer 104 on the side of the second insulating dielectric layer 103 away from the substrate 101, to reduce the occurrence of display defects caused by poor characteristics. the semiconductor device 10 provided in the embodiment above is a thin film transistor.

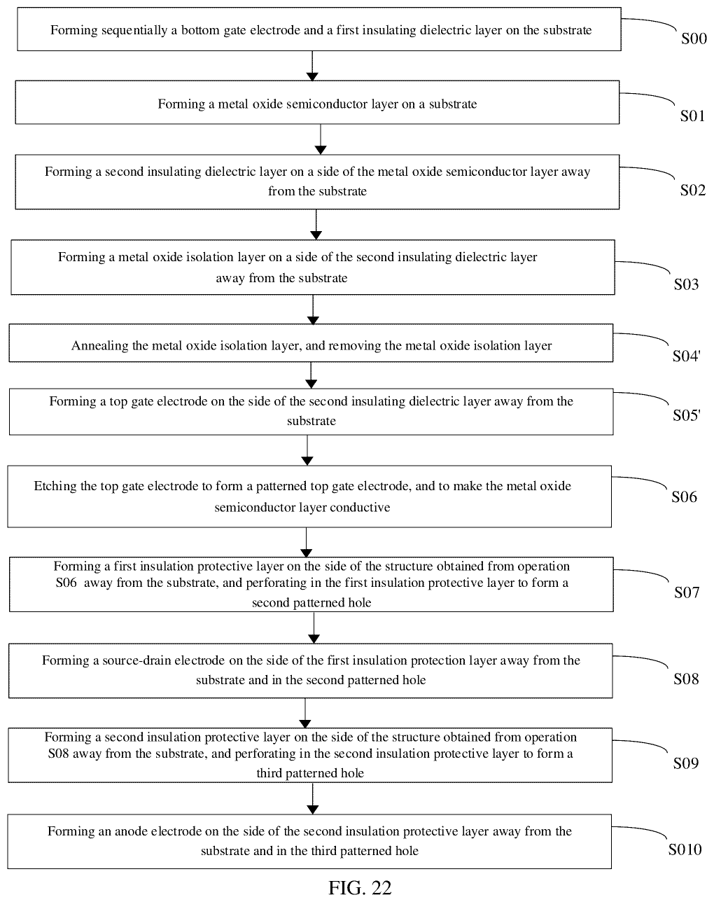

Referring to FIG. 22, FIG. 22 is a flow chart of a method for preparing an array substrate according to an embodiment of the present disclosure. A method for preparing an array substrate 100 is provided according to the embodiment of the present disclosure. This embodiment can be prepared on the basis of the first embodiment, or on the basis of the second embodiment. The following mainly takes the preparation method based on the second embodiment as an example. The preparation method of this embodiment further includes operation S09 and operation S010.

Operation S09: Forming a second insulation protective layer on the side of the structure obtained from operation S08 away from the substrate, and perforating in the second insulation protective layer to form a third patterned hole.

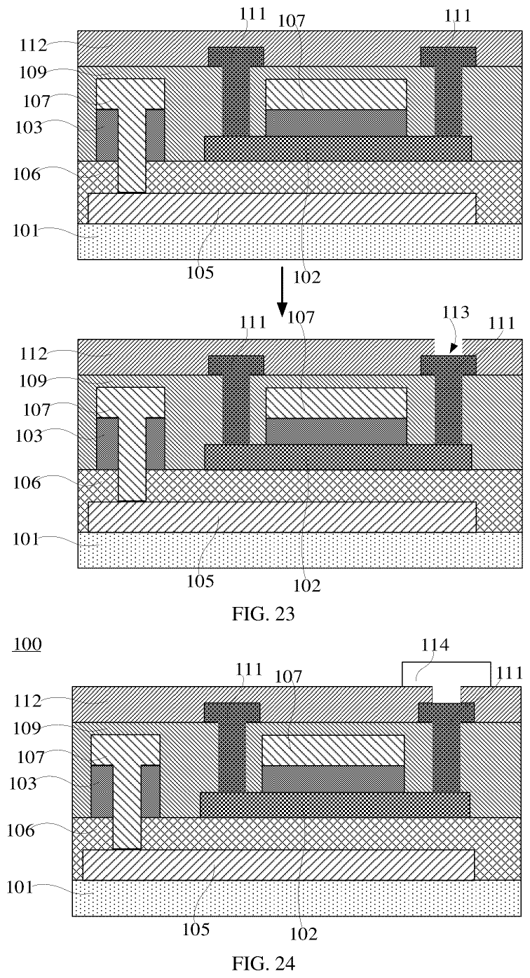

Referring to FIG. 23, FIG. 23 is a schematic structure view of operation S09. A second insulating protective layer 112 is formed by chemical vapor deposition, In some embodiments, the second insulating protective layer 112 may be a flattened layer, which includes but is not limited to a monolayer/multilayer structure of silicon nitride or silicon oxide, the second insulating protective layer 112 is also perforated by coating, exposing, developing, dry etching, and stripping to form a third patterned hole 113.

Operation S010: Forming an anode electrode on the side of the second insulation protective layer away from the substrate and in the third patterned hole.

Referring to FIG. 24, FIG. 24 is a schematic structure view of operation S010. The anode electrode 114 is formed by magnetron sputtering, and the film layer material includes but is not limited to indium tin oxide, indium zinc oxide, silver, molybdenum, niobium, titanium, and nickel, to complete the preparation of the array substrate 100 with annealing treatment, the annealing temperature range of 200° C.-280° C., the annealing time range of 25 min-45 min.

The disclosure further provides an array substrate 100, including a thin film transistor prepared by the above-mentioned method for preparing semiconductor device 10.

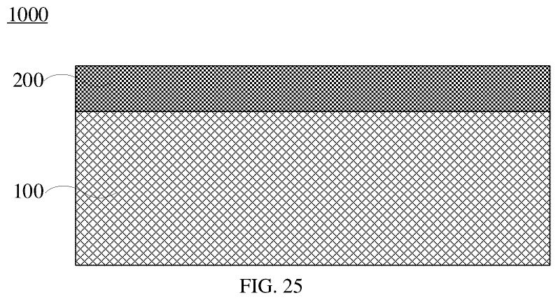

Referring to FIG. 25, FIG. 25 is a structure schematic view of a display panel according to an embodiment of the present disclosure. The disclosure further provides a display panel 1000, including the array substrate 100 mentioned above and the light-emitting layer 200. Among them, the light-emitting layer 200 is disposed on a side of the array substrate 100 and is electrically connected to the array substrate 100. The light-emitting layer 200 includes a light-emitting element, which can be an OLED or an LED. The embodiments of the present disclosure are not specifically limited to the application of the aforementioned display panel 1000. The display panel 1000 can be applied to various display devices, such as handheld devices (smartphones, tablets, etc.), wearable devices (smart wristbands, wireless headphones, smartwatches, smart glasses, etc.), in vehicle devices, terminal devices, etc.

It is apparent to those skilled in the art that the present disclosure is not limited to the details of the exemplary embodiments described above, and that it can be implemented in other specific forms without departing from the spirit or essential features of the present disclosure. Accordingly, the embodiments are to be regarded as exemplary and non-limiting in every respect, and the scope of the present disclosure is limited by the claims and not by the foregoing description and is intended to encompass all variations falling within the meaning and scope of the equivalent elements of the claims. Any appended markings in the claims should not be regarded as limiting the claims involved.

The above description are only embodiments of the present disclosure, and do not limit the scope of the present disclosure. Any equivalent structure or equivalent process transformation made by using the contents of the description and drawings of the present disclosure, or directly or indirectly used in other related technical fields, are similarly included in the scope of patent protection of the present disclosure.

What is claimed is:

1. A method for preparing a semiconductor device, comprising:
forming a metal oxide semiconductor layer on a substrate;
forming a second insulating dielectric layer on a side of the metal oxide semiconductor layer away from the substrate; and
forming a metal oxide isolation layer on a side of the second insulating dielectric layer away from the substrate; wherein the metal oxide isolation layer is in contact with a surface of the second insulating dielectric layer away from the substrate, a concentration of elemental oxygen in the metal oxide isolation layer is greater than a concentration of elemental oxygen in the second insulating dielectric layer, and the concentration of elemental oxygen in the second insulating dielectric layer is greater than a concentration of elemental oxygen in the metal oxide semiconductor layer.

2. The method for preparing a semiconductor device according to claim 1, wherein the metal element of the metal oxide semiconductor layer comprises one or more of In, Ga, Zn, and Sn; and/or, the metal element of the metal oxide isolation layer comprises one or more of In, Ga, Zn, and Sn.

3. The method for preparing a semiconductor device according to claim 1, wherein the forming a metal oxide isolation layer on a side of the second insulating dielectric layer away from the substrate comprises:
forming the metal oxide isolation layer by sputtering on the surface of the second insulating dielectric layer away from the substrate in an atmosphere containing oxygen; wherein the oxygen flow rate in the atmosphere containing oxygen accounts for more than or equal to 7% of the entire atmosphere.

4. The method for preparing a semiconductor device according to claim 1, further comprising:
annealing the metal oxide isolation layer.

5. The method for preparing a semiconductor device according to claim 4, wherein the annealing the metal oxide isolation layer is performed under dry compressed air.

6. The method for preparing a semiconductor device according to claim 4, wherein the metal elements of the metal oxide semiconductor layer comprise In, Ga, and Zn, and the In element content is the same as the monomer content of other metal elements; the metal oxide isolation layer is a film structure with an In:Ga:Zn ratio range of 1˜8:1˜8:1˜8, the time range for annealing the metal oxide isolation layer is 45 min-75 min, and the annealing temperature range is 300° C.-450° C.; or
the metal elements of the metal oxide semiconductor layer comprise In, Ga, Zn, and Sn, and the In element content is higher than the monomer content of other metal elements; the metal oxide isolation layer is a film structure with an In:Ga:Zn ratio range of 1˜8:1˜8:1˜8, the time range for annealing the metal oxide isolation layer is 45 min-75 min, and the annealing temperature range is 260° C.-350° C.

7. The method for preparing a semiconductor device according to claim 1, further comprising: removing the metal oxide isolation layer.

8. The method for preparing a semiconductor device according to claim 7, wherein the semiconductor device is a thin film transistor, and the method further comprises:
forming a top gate electrode on the side of the second insulating dielectric layer away from the substrate after removing the metal oxide isolation layer.

9. The method for preparing a semiconductor device according to claim 7, wherein the semiconductor device is a thin film transistor, and the method further comprises:
forming sequentially a bottom gate electrode and a first insulating dielectric layer on the substrate before forming the metal oxide semiconductor layer on the substrate.

10. An array substrate, comprising a semiconductor device, wherein the semiconductor device is prepared by a method, comprising:
forming a metal oxide semiconductor layer on a substrate;
forming a second insulating dielectric layer on a side of the metal oxide semiconductor layer away from the substrate; and
forming a metal oxide isolation layer on a side of the second insulating dielectric layer away from the substrate; wherein the metal oxide isolation layer is in contact with a surface of the second insulating dielectric layer away from the substrate, a concentration of elemental oxygen in the metal oxide isolation layer is greater than a concentration of elemental oxygen in the second insulating dielectric layer, and the concentration of elemental oxygen in the second insulating dielectric layer is greater than a concentration of elemental oxygen in the metal oxide semiconductor layer.

11. The array substrate according to claim 10, wherein the metal element of the metal oxide semiconductor layer comprises one or more of In, Ga, Zn, and Sn; and/or, the metal element of the metal oxide isolation layer comprises one or more of In, Ga, Zn, and Sn.

12. The array substrate according to claim 10, wherein the forming a metal oxide isolation layer on a side of the second insulating dielectric layer away from the substrate comprises:
forming the metal oxide isolation layer by sputtering on the surface of the second insulating dielectric layer away from the substrate in an atmosphere containing oxygen; wherein the oxygen flow rate in the atmosphere containing oxygen accounts for more than or equal to 7% of the entire atmosphere.

13. The array substrate according to claim 10, wherein the method further comprises: annealing the metal oxide isolation layer.

14. The array substrate according to claim 13, wherein the metal elements of the metal oxide semiconductor layer comprise In, Ga, and Zn, and the In element content is the same as the monomer content of other metal elements; the metal oxide isolation layer is a film structure with an In:Ga:Zn ratio range of 1˜8:1˜8:1˜8, the time range for annealing the metal oxide isolation layer is 45 min-75 min, and the annealing temperature range is 300° C.-450° C.; or
the metal elements of the metal oxide semiconductor layer comprise In, Ga, Zn, and Sn, and the In element content is higher than the monomer content of other metal elements; the metal oxide isolation layer is a film structure with an In:Ga:Zn ratio range of 1˜8:1˜8:1˜8, the time range for annealing the metal oxide isolation layer is 45 min-75 min, and the annealing temperature range is 260° C. −350° C.

15. The array substrate according to claim 10, wherein the method further comprises: removing the metal oxide isolation layer.

16. A display panel, comprising:
an array substrate; and
a light emitting layer, disposed on a side of the array substrate and electrically connected to the array substrate;
wherein the array substrate comprises a semiconductor device prepared by a method comprising:
forming a metal oxide semiconductor layer on a substrate;
forming a second insulating dielectric layer on a side of the metal oxide semiconductor layer away from the substrate; and
forming a metal oxide isolation layer on a side of the second insulating dielectric layer away from the substrate; wherein the metal oxide isolation layer is in contact with a surface of the second insulating dielectric layer away from the substrate, a concentration of elemental oxygen in the metal oxide isolation layer is greater than a concentration of elemental oxygen in the second insulating dielectric layer, and the concentration of elemental oxygen in the second insulating dielectric layer is greater than a concentration of elemental oxygen in the metal oxide semiconductor layer.

17. The display panel according to claim 16, wherein the metal element of the metal oxide semiconductor layer comprises one or more of In, Ga, Zn, and Sn; and/or, the metal element of the metal oxide isolation layer comprises one or more of In, Ga, Zn, and Sn.

18. The display panel according to claim 16, wherein the forming a metal oxide isolation layer on a side of the second insulating dielectric layer away from the substrate comprises:
forming the metal oxide isolation layer by sputtering on the surface of the second insulating dielectric layer away from the substrate in an atmosphere containing oxygen; wherein the oxygen flow rate in the atmosphere containing oxygen accounts for more than or equal to 7% of the entire atmosphere.

19. The display panel according to claim 16, wherein the method further comprises: annealing the metal oxide isolation layer.

20. The display panel according to claim 16, wherein the method further comprises: removing the metal oxide isolation layer.
